(19) United States
(12) Patent Application Publication
(10) Pub. No.: US 2007/0133275 A1
(43) Pub. Date: Jun. 14, 2007

(54) Low-power reading reference circuit for split-gate flash memory

(75) Inventors: Meng-Fan Chang, Taipei City (TW); Hsien-Yu Pan, Pingtung County (TW); Ding-Ming Kwai, Hsinchu County (TW); Yung-Fa Chou, Kaohsiung (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Intellectual Property Libarary Company, Hsinchu City (TW)

(21) Appl. No.: 11/473,250

(22) Filed: Jun. 22, 2006

(30) Foreign Application Priority Data
Dec. 7, 2005 (TW) 094143230

(51) Int. Cl. G11C 16/06

(52) U.S. Cl. 365/185.2

(57) ABSTRACT

A low-power reading reference circuit for split-gate flash memory includes at least a pair of first reference cell and a second reference cell, which provides a reading reference current to regular cells of the split-gate flash memory. A first floating gate of the first reference cell and a second floating gate of the second reference cell are connected to an output of a logic circuit. The logic circuit receives at least one external state signal to determine whether the split-gate flash memory is ready to switch to reading mode or not, and then switches the first floating gate and the second floating gate between the state of activated and deactivated, so as to activate the first reference cell or the second reference cell to provide the reference current.

### CROSS-REFERENCE TO RELATED APPLICATIONS

This non-provisional application claims priority under 35 U.S.C. § 119(a) on Patent Application No(s). 094143230 filed in Taiwan, R.O.C. on Dec. 7, 2005, the entire contents of which are hereby incorporated by reference.

### BACKGROUND OF THE INVENTION

1. Field of Invention

The present invention relates to a kind of reading reference circuit for semiconductor memory component, and more particularly to a low-power reading reference circuit for split-gate flash memory, which can provide a fast and steady reference current during reading mode and has low power consumption in erasing or programming mode..

2. Related Art

Referring to FIG. 1, a semiconductor structure layout of a split-gate flash memory is shown, which has plural pairs of reference cell 1, 2. As the direction and layout of the sources 1a, 2a and the drains 1b, 2b of the reference cell 1, 2 are different from each other in manufacturing process, the electrical performances of the same pair of reference cells 1, 2 are different. A reading reference current provided by a reading reference circuit is utilized to solve the problem due to the differences of the electrical performances of the pair of reference cells 1, 2. If the reading reference current is not provided in time, the split-gate flash memory may be malfunctioned.

Referring to FIG. 2, a reading reference circuit of prior art is shown, which includes split-gate type field effect transistors as a first reference cell 10 and a second reference cell 20. There may be one pair or plural pairs of the coupled first reference cell 10 and second reference cell 20. The floating gates 10a, 20a of the first, second reference cells 10, 20 are connected to the control gates 10b, 20b, while the control gates 10b, 20b are connected to two terminals of a signal source 30, of which the signals generated by two terminals are inverse in phase, such that the first and the second reference cells is controlled by two control signals 30a, 30b which are inverse in phase. The sources 10c, 20c of the first reference cell 10 and the second reference cell 20 are connected to a source line. When the control gate 10b of the first reference cell 10 is set to be high by control signal 30b, the drain 10d of the first reference cell 10 will provide reading reference current. And meanwhile, the control signal 30a of the second reference cell 20 is low, such that the drain 20d of the second reference cell 20 is deactivated. On the contrary, when the control gate 20b of the second reference cell 20 is set to be high by control signal 30b, the drain 20d of the first reference cell 10 will provide reading reference current. And meanwhile the control signal 30b of the first reference cell 10 is low, such that the drain 10d of the first reference cell 10 is deactivated.

In the split-gate flash memory aforementioned, floating gates 10a, 20a are connected to control gates 10c, 20c, the voltage of floating gates 10a, 20a are risen when the control gates 10b, 20b are set to be high by the source signal, to activate the reference cells. However, a period of time waiting for the voltage of the floating gates 10a, 20a existed, to rise to threshold or activating voltage after signal source provide a voltage to set the floating gates 10a, 20a due to the high resistance existed on the connector between the metal line and the floating gates 10a, 20a, then the reference cell begin to provide current. Correspondingly, there is a time difference existed between the beginning of reading mode of split-gate flash memory and the moment when one of the reference cell 10, 20 is ready to provide reading reference current, which causes a long response time of this circuit. Meanwhile, both the control gates 10b, 20b and the floating gates 10a, 20a are connected to the signal source, so either of the first and second reference cells is on, which will cause extra power consuming.

Referring to FIG. 3, a reference cell circuit provided by U.S. Pat. No. 6,396,740 is shown. In which the floating gates 10a, 20a of the reference cell are connected to a constant voltage source VDD, and the voltages of floating gates 10a, 20a are at the activating voltage (namely be high) at any time, so that it is not necessary to wait for the voltage of floating gate 10a, 20a to rise to activate the first or second reference cell 10, 20 when the flash memory switches the accessed regular cells or switches to reading mode from other modes, which means the decrease of the time to waiting for the switching of the floating gates 10a, 20a of reference cells at the beginning of a reading cycle. However, floating gates 10a, 20a are high at any time in U.S. Pat. No. 6,396,740, so one of the first and second reference cells 10, 20 is always on, which causes extra power consuming for other modes.

### SUMMARY OF THE INVENTION

Due to the high resistance existed between the floating gate and correspondent voltage source, a period of time waiting for the voltage of the floating gate existed to rise to threshold or activating voltage then activate the reference cell to provide reading reference current. Additionally, either of reference cells is on during the work process of the circuit even in nonreading mode, which will cause extra power consuming. To solve this problem, the object of the present invention is to provide a low-power reading reference circuit for split-gate flash memory, for changing the voltage of floating gate of reference cell in advance, so that reading reference current is provided by reference cell at the moment of the reading mode begins. And the voltage of the floating gate rises right before the moment when the providing of reading reference current is needed, so a period of time is not necessary to wait for the voltage floating gate to rise after the reading mode begins. Meanwhile all reference cells are actually off when the reading reference voltage is not in demand.

To achieve the object mentioned above, the present invention provides a low-power reading reference circuit for split-gate flash memory, comprising a first reference cell, a second reference cell, and logic circuit. The first reference cell includes a first floating gate, a first control gate and a first drain. The second cell includes a second floating gate, a second control gate and a second drain, wherein the first control gate and the second control gate are connected to two signals which are inverse in phase for activating one of the first and second reference cell, then enable the first drain or the second drain to provide a reading reference current. The logic circuit is connected to the first floating gate and the second floating gate, and the logic circuit receives at least one external state signal to determine whether the split-gate flash memory is ready to switch to reading mode or not, then switch the first floating gate and the second floating gate between the state of activated and deactivated, so as to activate the first reference cell or the second reference cell to provide reference current.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow illustration only, and thus are not limitative of the present invention, and wherein:

FIG. 1 is a semiconductor structure layout of a split flash memory of the prior art.

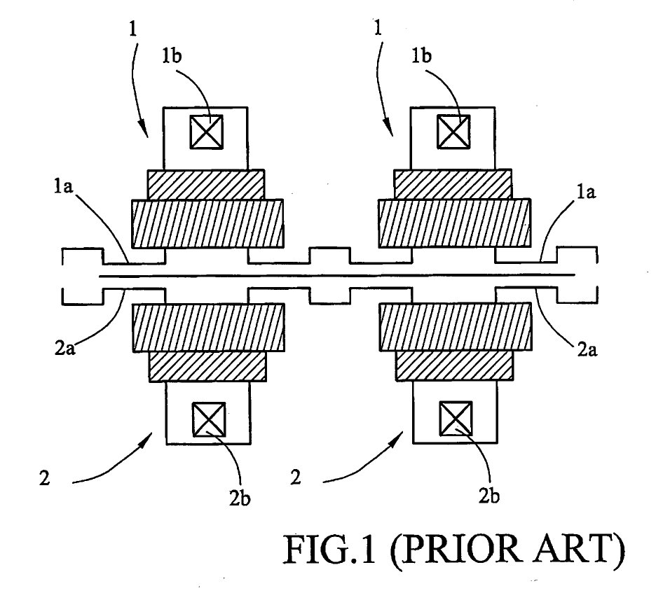

FIG. 2 is a reading reference circuit of the prior art.

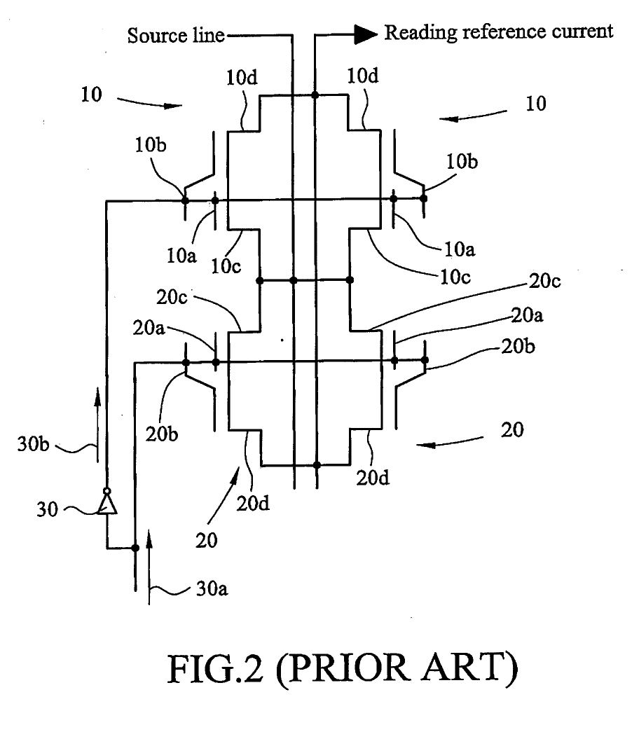

FIG. 3 is another reading reference circuit of prior art.

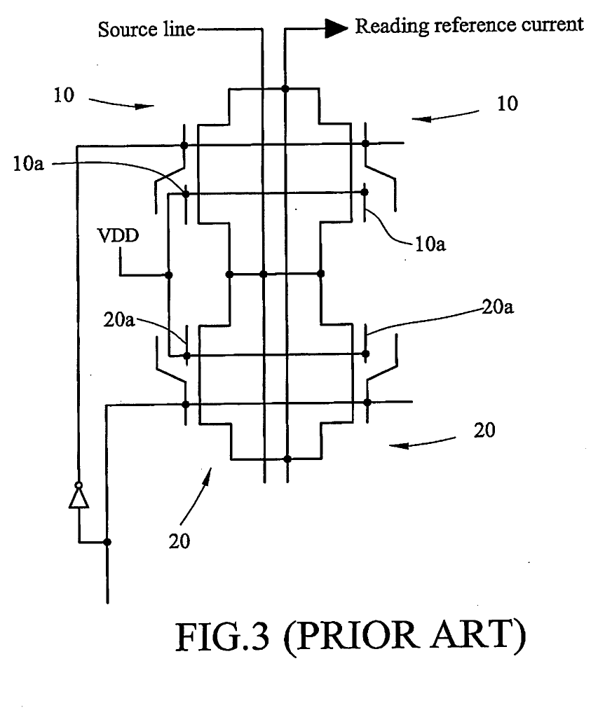

FIG. 4 is a reading reference circuit of a first embodiment of the present invention.

FIG. 5 is schematic diagram illustrating the cycle of a first embodiment of the present invention.

FIG. 6 is a reading reference circuit of a second embodiment of the present invention.

### DETAILED DESCRIPTION OF THE INVENTION

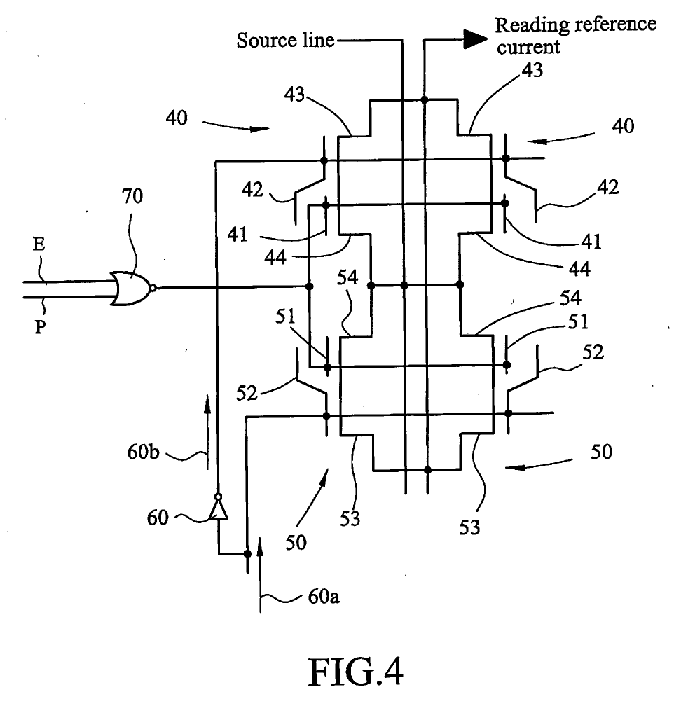

Referring to FIG. 4, a low-power reading reference circuit of a first embodiment of the present invention is provided, which includes a pair of first reference cell 40 and a second reference cell 50. The first reference cell 40 and the second reference cell 50 respectively provide reading reference current to corresponding regular cell in reading mode. There may be one pair of the first reference 40 and the second reference 50, or plural pairs of that, which corresponds to plural regular reference cells.

The first reference cell 40 includes a first floating gate 41, a first control gate 42, a first drain 43 and a first source 44. The second reference cell 42 is similar to the first one, it includes a second floating gate 51, a second control gate 52, a second drain 53 and a second source 54. The first source 44 and the second source 54 are connected to a source line, while the first control gate 42 and the second control gate 52 are connected to two terminals inverse in phase of a signal source 60. An inverter can be applied as the signal source 60. By inputting a control signal 60a to one terminal of the signal source 60, an inverse control signal 60b is generated. So the two terminals of signal source 60 will respectively be logic high and logic low, for enabling the first control gate 42 and the second control gate 52 to be logic high or logic low. Subsequently, one of the first reference cell 40 or the second reference cell 50 is activated, and then the first drain 43 or the second drain 53 will provide reading reference current.

Take FIG. 4 as an illustration, when the control signal 60a is logic high, the second control gate 52 is enabled to be logic high by the control signal 60a. Whereas the control signal 60a is inversed by the signal source 60 to generate the inverse control signal 60b, which is logic low, at other terminal of the signal source 60. Thus the second reference cell 50 is activated, so the second drain 53 can provide reading reference current. Meanwhile the first reference cell 60 is deactivated.

On the contrary, when the control signal 60a is logic low, the second control gate 52 will be set to be low by the control signal 60a. Whereas the control signal 60a is inverted by the signal source 60 to generate the inverse control signal 60b, which is logic high, at the other terminal of the signal source 60. Thus the first reference cell 40 is activated and the second reference cell is deactivated. The first drain 43 can provide reading reference current. Thereby, the first drain 43 or the second drain 53 will be selected to provide regular cell with reading reference current by switching the first control gate 42 and the second control gate 52 between the states of activated and deactivated.

And the logic circuit 70 is used for determining whether the first reference cell and the second reference cell is activated to provide reading reference current for reading circuits at reading mode or not. The first floating gate 41 and the second floating gate 51 are connected to the logic circuit 70, which can receive at least one external state signal to change state of itself, and then switch the first floating gate 41 and the second floating gate 51 between the states of activated and deactivated. In this embodiment, a NOR gate is applied as the logic circuit 70, which is used for receiving a first external state signal E and a second external state signal P, wherein the first external state signal E indicates whether the erasing mode of the split-gate flash memory is in on or off. And the second external state signal P indicates whether the programming mode of split-gate flash memory is in on or off. At least one of the first external state signal E and the second external state signal P is logic high when the split-gate flash memory is in erasing mode or programming mode, namely the split-gate flash memory is not in reading mod. The output of logic circuit 70 will be logic low, correspondingly both the first floating gate 42 and the second floating gate 52 are logic low, that means the first reference cell 40 and the second reference cell 50 are both deactivated, thereby the first drain 43 and the second drain 53 will not provide the split-gate flash memory with reading reference current at erasing and programming modes, also no power will be consumed by the first reference cell 40 and the second reference cell 50.

When the split-gate flash memory is neither in erasing mode nor in programming mode, both the first external state signal E and the second external signal P are logic low, namely the split-gate flash memory is in or ready to be in reading mode, so the output of logic circuit 70 will be logic high and the voltage of the first floating gate 41 and the second floating gate 51 begin to rise to be logic high (namely to the threshold or the activating voltage), correspondingly the first reference cell 40 and the second reference cell 50 are activated to enable the first drain 43 and the second drain 53 provide the split-gate flash memory with reading reference current. Which one of two drains of reference cells will be selected and activated to provide reference current is determined by the first control gate 42 and the second control gate 52, and the state of activated or deactivated of the first control gate 42 and the second control gate 52 is determined by the source signal 60 referred above.

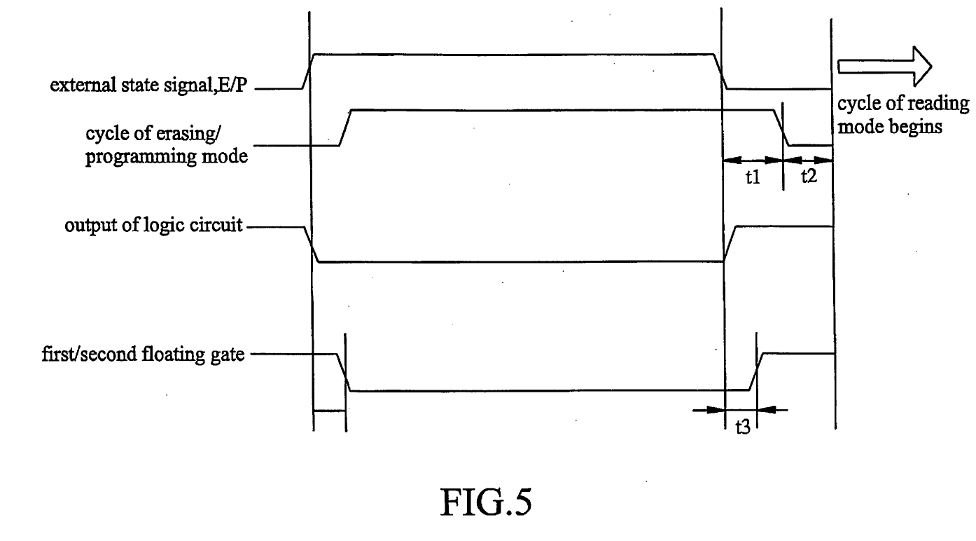

Referring to FIG. 5, it is necessary to switch of state signals (E and P) to be logic low before the end of the cycle of erasing mode or programming mode, to ensure the completion of device-discharging activity after high-voltage operations. In this switching process of the embodiment of the present invention, the output of logic circuit 70 has plenty time, t1+t2 (approximately more than 6 μs), to be switched to logic high before the reading mode begins. Namely as the erasing mode and programming mode end, the first external state signal E and the second external state signal P are switched to be logic low, the logic circuit 70 can be switched to be logic high in advance to change the state of the reference cells. That means the voltages of first floating gate 41 and second floating gate 51 begin to rise before the split-gate memory switches to reading mode, and the voltage become steady before the beginning of the cycle of reading mode that the regular cell switches to. Thereby, the time (t3) that the voltage of the first floating gate 41 and the second floating gate 51 rises will not affect the actual cycle of reading mode. That is, even there is high resistance between the logic circuit 70 and the first and the second floating gates 41, 51, the excessively long time waiting for the first and second floating gate to rise to a steady voltage is eliminated.

Based on the reading reference circuit, a method for providing reading reference current to a split-gate flash memory is provided, and which comprising the following steps. (1) Connecting the output of the logic circuit 70 to the first floating gate 41 of the first reference cell 40 and the second floating gate 51 of the second reference cell 50. (2) Providing at least one external state signal to the logic circuit 70, to switch the first floating gate 41 and the second floating gate 51 between the states of activated and deactivated. Based on the first embodiment, the external state signal can be either first external state signal E or second external signal P, respectively indicates erasing mode and programming mode of the split-gate flash memory. The split-gate flash memory is ready to end erasing mode or programming mode when both the external state signal E and the external state signal P are logic low. (3) Connecting the first control gate 42 of the first reference cell 40 and the second control gate 52 of the second reference cell 50 to two terminals, which are inverse in phase, of a signal source 60, such as an inverter. Inputting a control signal 60a to one terminal of the inverter, then an inverse control signal 60b will be generated on the other terminal for switch between the logic state of logic high and logic low of the first control gate 42 and the second control gate 52, so as to activate one of the first reference cell 40 and the second reference cell 50. The signals generated on two terminals of the signal source 60 are inverse in phase, so one of the first control gate 42 and the second control gate 52 is logic high to activate the correspondingly reference cell (first or second reference cell). (4) One of the first reference cell and the second reference cell will be activated, so the split-gate flash memory in reading mode is provided with reading reference current by first drain 43 or second drain 53.

In the method referred above, the first floating gate 41 or the second floating gate 51 can change the voltage before the ending of erasing mode and programming mode by the first external signal E and the second external state signal P, so the whole reading reference circuit will switch to reading mode in advance. The voltage of the first floating gate 41 or the second floating gate 51 can rise and be steady when the cycle of reading mode begins. Thus it is not necessary to wait for the voltage of the first floating gate 41 or the second floating gate 51 to rise after the cycle of reading mode begins. That means a shorter time of reading reference.

Additionally, in the erasing mode or programming mode, at least one of the first external state signal E and the second external state signal P is high, and the output of logic circuit is low. Namely, the logic circuit can set both the first and the second reference cell 40, 50 deactivated of the split-gate flash memory is in erasing mode or programming mode, such that no extra power will be consumed. That means lower power consuming of the reading reference circuit in erasing and programming modes.

The logic circuit 70 is not confined to a NOR gate. And also the first and second external state signal E, P are not necessary to be low to enable the logic circuit 70 to activate the first and second reference cell 40, 50. That means, the type of logic circuit 70 or the states between high and low of the external state signals received is not confined to the arrangement in this embodiment.

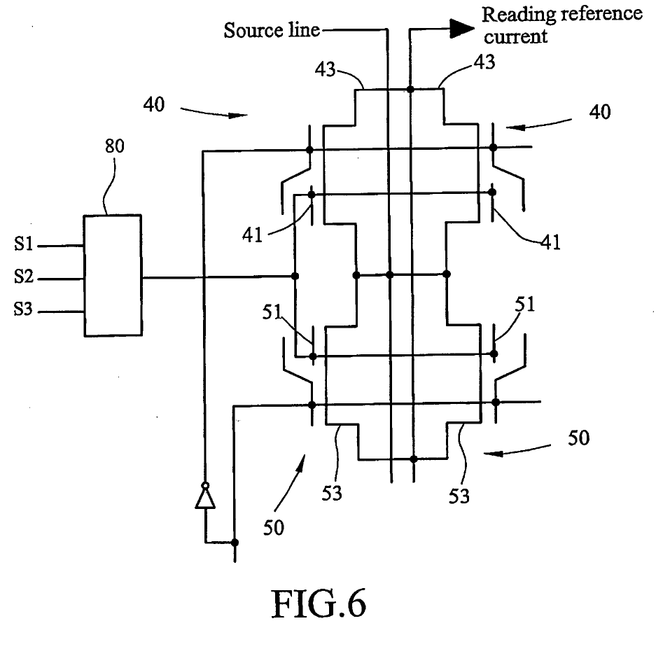

Referring to FIG. 6, a reading reference circuit for split-gate flash memory of a second embodiment of the present invention is provided in which the structure and the arrangement of the first reference cell 40 and the second reference cell 50 are similar to the first embodiment. The difference is that the logic circuit 80 of the second embodiment receives a plurality of external signals S1, S2, S3 at the same time. These external signals S1, S2, S3 indicate the “on” or “off” state of erasing mode and programming mode in the split-gate flash memory. The logic circuit can activate the reading reference circuit to provide the split-gate flash memory with a steady reading reference current before reading mode when it appears that the erasing mode and the programming mode are all ready to be off.

The logic circuits 70, 80 are used to determine which mode of erasing, programming or reading the split-gate flash memory is in by receiving the external state signals, and then switch the mode of the first and second floating gate 41, 51 to activate the reading reference circuit to provide reading reference current in reading mode. When erasing and programming modes are ready to be off, the external state signal will change the output of logic circuits 70, 80. Thus the voltage of the first and the second floating gates begin to rise before the cycle of the reading mode begins. Thereby the voltage of first and second floating gates 43, 53 will become steady to activate the reading reference circuit when the cycle of reading mode begin, so the first and second drain 43, 53 can provide reading reference current without waiting for the voltage of the first and second floating gate 41, 51 to rise after the cycle of reading mode begins.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A low-power reading reference circuit for split-gate flash memory, comprising:
a first reference cell including a first floating gate, a first control gate and a first drain;
a second reference cell including a second floating gate, a second control gate and a second drain, wherein the first control gate and the second control gate are respectively connected to two signals which are inverse in phase, for activating one of said first reference cell and said second reference cell, enabling the first drain or the second drain to provide a reading reference current; and
a logic circuit connected to said first floating gate and said second floating gate, said logic circuit receiving at least one external state signal for switching the first floating gate and the second floating gate between the states of activated and deactivated.

2. The low-power reading reference circuit as claimed in claim 1, wherein said logic circuit receives a first external state signal and a second external state signal for switching the first floating gate and the second floating gate between the states of activated and deactivated.

3. The low-power reading reference circuit as claimed in claim 2, wherein said first external state signal indicates whether a erasing mode of the split-gate flash memory is on or off, and the second external state signal indicates whether a programming mode of the split-gate flash memory is on or off.

4. The low-power reading reference circuit as claimed in claim 3, wherein said logic circuit activates said reference circuit to provide a reading reference current when both the erasing mode and the programming mode are off.

5. The low-power reading reference circuit as claimed in claim 2, wherein said logic circuit enables the first floating gate and the second floating gate to be logic high when both the first external state signal and the second external state signal are logic low.

6. The low-power reading reference circuit as claimed in claim 2, wherein said logic circuit is a NOR gate.

7. The low-power reading reference circuit as claimed in claim 1, wherein said logic circuit receives a plurality of external state signals, to determine whether said split-gate flash memory is in the mode of erasing, programming or reading, and then switches said first floating gate and said second floating gate between the state of activated and deactivated.

8. The low-power reading reference circuit as claimed in claim 1, wherein said logic circuit receives a plurality of external state signals to determine whether the split-gate flash memory is in the mode of erasing, programming or reading, and then activates said reading reference circuit to provide said reading reference current.

9. The low-power reading reference circuit as claimed in claim 1, wherein said first control gate and said second control gate are respectively connected to two terminals of an inverter, of which the two terminals generate two signals inverse in phase.

10. A method to for providing reading reference current to split-gate flash memory, comprising the steps of:
connecting an output of a logic circuit to a first floating gate of a first reference cell and a second floating gate of a second reference cell;
providing at least one external state signal to said logic circuit to switch said first floating gate and said second floating gate between the state of activated and deactivated;
connecting the first control gate of said first reference cell and the second control gate of said second reference cell to two signals inverse in phase, to activate one of said first reference cell and said second reference cell; and
providing a reading reference current by a first drain of said first reference cell or a second drain of said second reference memory cell.

11. The method as claimed in claim 10, wherein said logic circuit receives a first external state signal and a second external state signal for switching the first floating gate and the second floating gate between the states of activated and deactivated.

12. The method as claimed in claim 11, wherein said first external state signal indicates whether a erasing mode of the split-gate flash memory is on or off, and the second external state signal indicates whether a programming mode of said split-gate flash memory is on or off.

13. The method as claimed in claim 12, wherein said logic circuit activates said reading reference circuit to provide the reading reference current when both the erasing mode and the programming mode are off.

14. The method as claimed in claim 11, wherein said logic circuit enables the first floating gate and the second floating gate to be logic high when both the first external state signal and the second external state signal are logic low.

15. The method as claimed in claim 11, wherein said logic circuit is a NOR gate.

16. The method as claimed in claim 10, wherein said logic circuit receives a plurality of external state signals, to determine whether the split-gate flash memory is in the mode of erasing, programming or reading, and then switches said first floating gate and said second floating gate between the state of activated and deactivated.

17. The method as claimed in claim 16, wherein said logic circuit activate a reading reference circuit to provide the reading reference current when said external signals indicate that the erasing mode and programming mode are off.

18. The method as claimed in claim 10, wherein the first control gate and the second control gate are respectively connected to two terminals of an inverter, of which the two terminals generate two signals inverse in phase.
